(19) United States
(12) Patent Application Publication
(10) Pub. No.: US 2015/0207004 A1
(43) Pub. Date: Jul. 23, 2015

(54) Trough Shaped Fresnel Reflector Solar Concentrators

(71) Applicant: Jeffrey Michael Citron, Tucson, AZ (US)

(72) Inventor: Jeffrey Michael Citron, Tucson, AZ (US)

(21) Appl. No.: 14/160,937

(22) Filed: Jan. 22, 2014

(51) Int. Cl. H01L 31/0525; F24J 2/24; H01L 31/052; F24J 2/12

(52) U.S. Cl. CPC H01L 31/058; F24J 2/12; F24J 2/24; H01L 31/0525

(57) ABSTRACT

The Present invention is a trough shaped solar concentrator with Fresnel strip reflectors disposed in a generally linear V shaped configuration. The present invention shows two unique geometrical supporting structures for the strip Fresnel reflectors. The concentrator is shown in several preferred embodiments as a concentrating solar energy collector with different types of solar energy receiving elements disposed at the focal area of the concentrator.

This application is a Continuation-in-part of this inventor's prior filed application Ser. No. 13/337,206, filed Dec. 26, 2011.

### BACKGROUND OF THE INVENTION

The present invention is in the field of solar concentrators. More particularly the present invention is shown in the configuration of a solar collector whose purpose is to concentrate solar energy and convert it into other useful forms of energy, although this is not intended to limit its use to that purpose.

Prior art trough shaped solar concentrators having flat strip Fresnel reflectors have been shown with supporting structure for the linear Fresnel reflectors in the form of a flat sheet or panel. This flat panel support structure for the Fresnel reflectors is expensive and may be replaced with other structural designs that may be produced at less cost.

### SUMMARY OF THE INVENTION

The present invention is a solar energy concentrator. More particularly it is shown in the preferred embodiment of a solar energy collector. As a solar energy collector it encompasses the solar energy concentrator of the present invention and a receiver element for receiving the concentrated solar energy and converting it to another form of energy. The present invention is comprised of a solar concentrator made of multiple flat linear reflective surfaces in the general shape of a linear trough that reflect and concentrate the solar energy at a linear area located at or above the trough aperture and parallel to the trough structure. More particularly the flat linear reflective surfaces collectively, effectively comprise a Fresnel reflector concentrating the solar energy along the width of line focal point of the Fresnel reflector. The Fresnel reflector of the present invention effectively forms steps along the generally V shaped trough structure of the present concentrator. In one preferred embodiment by putting a solar energy receiving element at the line focal area of the trough shaped Fresnel reflector a solar energy collector is created. To keep the cost of the structural support for the Fresnel reflectors low, two unique types of structural support for the Fresnel reflectors are shown as the subject of the present invention. These embodiments with other than flat panel supporting members for the Fresnel reflectors are the new and unique combination of the present invention.

Further aspects of the invention incorporating other than flat panel structural support for the Fresnel reflectors will become apparent from consideration of the drawings and the ensuing description of preferred embodiments of the invention. A person skilled in the art will realize that other embodiments of the invention are possible and that the details of the invention can be modified in a number of respects, all without departing from the inventive concept. Thus, the following drawings and description are to be regarded as illustrative in nature and not restrictive.

### BRIEF DESCRIPTION OF THE DRAWINGS

FIG. 1 is a cross-sectional drawing showing the present invention with two unique types of support structure for the Fresnel reflectors.

FIG. 2 is a view of the lattice support structure shown on the left side in FIG. 1.

FIG. 3 is a cross-sectional drawing of the present invention showing an alternate solar energy receiving element.

FIGS. 4a, b and c show alternate embodiments of the solar energy receiving element.

FIG. 5 is a perspective view of the present invention showing the zig zag Fresnel reflector structure.

FIG. 6 is a perspective view of the present invention showing the lattice support structure for the Fresnel reflectors.

### DETAILED DESCRIPTION OF THE INVENTION

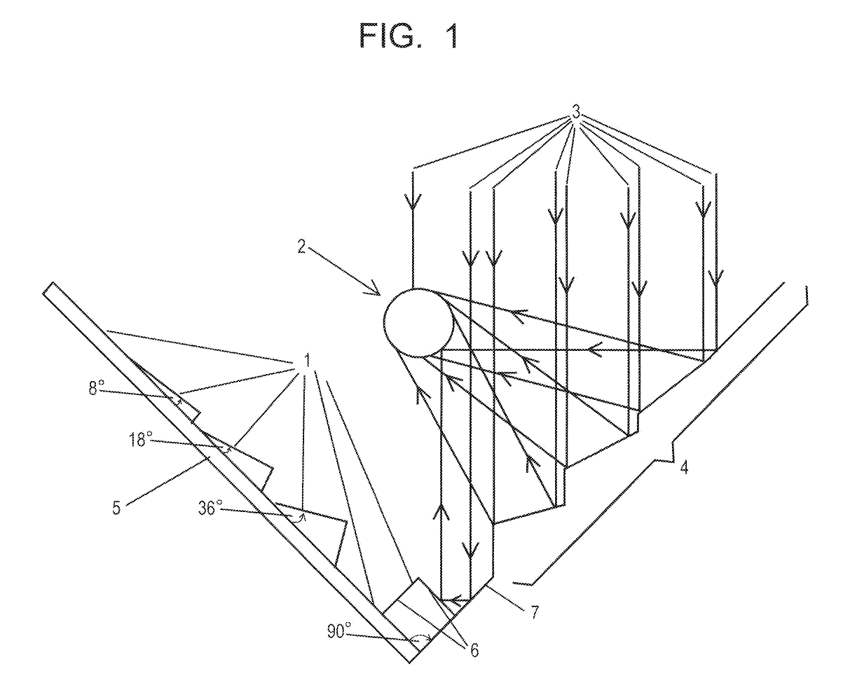

FIG. 1 shows a cross-sectional view of the present invention a linear Fresnel trough concentrator, utilizing flat reflectors 1 and having said reflectors disposed upon an underlying V shape. In this illustration the invention is shown in one of its preferred embodiments as a solar collector with a receiving element 2 disposed at the focal area of the Fresnel concentrator. The receiving element in this particular drawing is a round tube 2 coated with a solar radiation absorptive coating designed to receive the concentrated solar energy, convert it to heat and transmit that heat to a fluid flowing inside the tube 2. Said flowing fluid then transports the heat for useful application. To illustrate the operation of the concentrator, solar rays 3 are shown reflecting off reflectors 1 and concentrating on and being absorbed by receiver 2. As with most trough concentrators, the present invention needs to track the apparent movement of the sun across the sky in at least one direction. FIG. 1 shows the invention with two 4 and 5 of its unique structural configurations for supporting the Fresnel reflectors 1. Indicator 4 shows the Fresnel reflectors supported by a structure in a zig zag configuration. In this configuration reflective mirrors or a reflective poly film may be mounted on an underlying zig zag structure or the reflectors 1 may be polished sections of a metal zig zag panel. Indicator 5 shows the cross-section of an underlying lattice support structure for the Fresnel reflectors 1. It is here to be noted that the reflecting structure 6 working in conjunction with reflectors 7 are only on possible configuration and may be replaced with a single Fresnel reflecting step at the position of reflecting surface 7. It is also to be noted that the angles shown in this illustration including the underlying V shape angle of 90 degrees are only illustrative and the invention may be built with other angles.

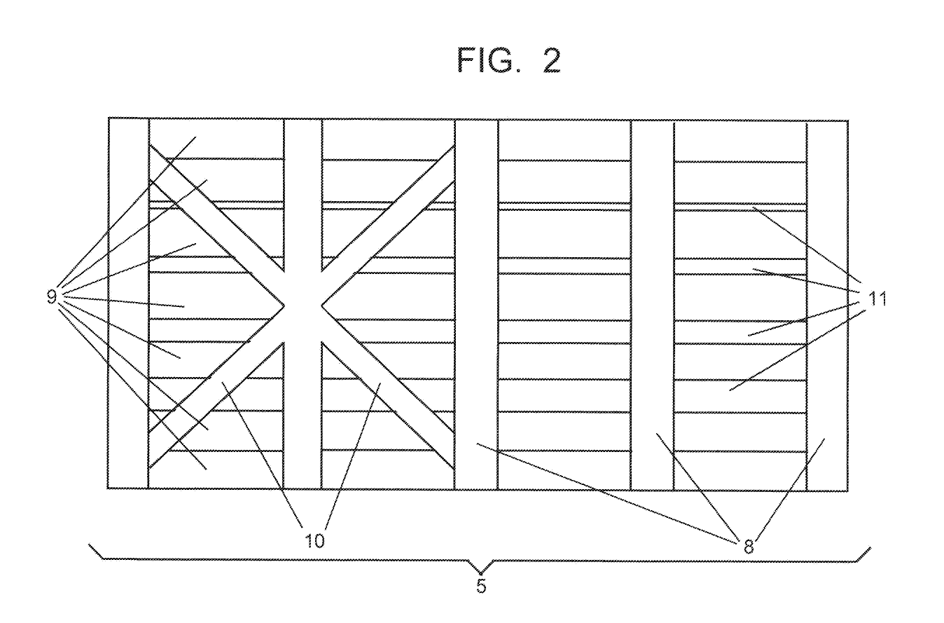

FIG. 2 shows a side view of the lattice support structure 5 which is one embodiment of this invention. This lattice structure is created by vertical support members 8 which are interconnected with horizontal support members 9. In addition or alternatively diagonal support members 10 may be connected with the horizontal support members 8. Basically it is necessary to create a rigged support structure for the Fresnel reflectors. Because the Fresnel reflectors are themselves horizontal structures in the concentrator they may be mounted on the horizontal support members 9 or the horizontal support members 9 may incorporate the Fresnel reflectors, as in the situation where the horizontal support members 9 are made of a metal material that incorporates highly polished reflector surfaces that are the Fresnel reflectors. The vertical 8 and diagonal 10 support members maybe made from stock material with essentially a rectangular cross-section or they may be made from stock material with a U channel cross-section. The horizontal support members may be a flat structural material of sufficient gauge to resist deformation during wind loading upon which the Fresnel reflectors are mounted. Other structural shapes and various construction techniques may be employed to create the lattice support structure for the Fresnel reflectors and the previous descriptions are to be considered as illustrative and not limiting. It is to be noted that as a consequence of the optical design of this invention, using flat Fresnel reflectors disposed upon the flat sides of a V shape and the requirement that none of the Fresnel reflectors shade adjacent Fresnel reflectors disposed closer to the vertex, joining point, of the V shape, there will be spaces 11 between some adjacent Fresnel reflectors and their horizontal support members in such a lattice structure.

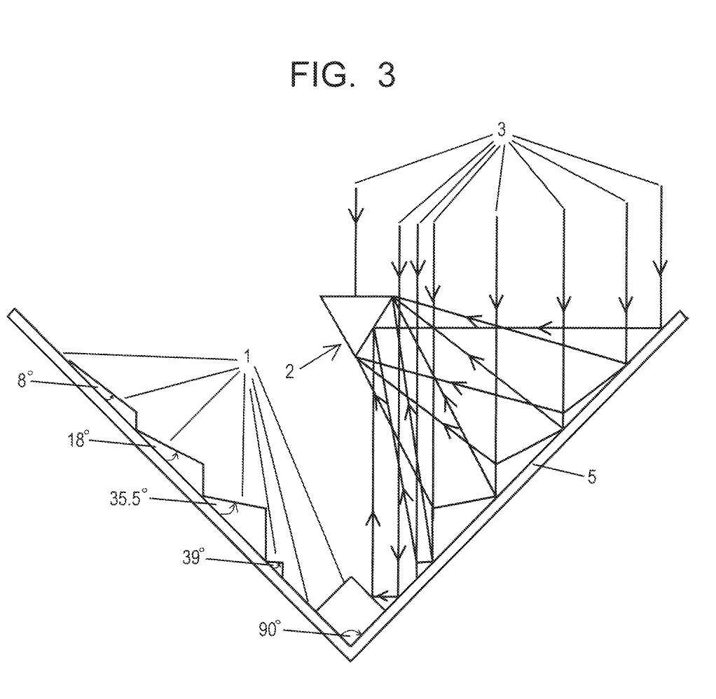

FIG. 3 shows a cross-section of the present invention with a triangular tube 2 as the receiver and the lattice structure 5 supporting the Fresnel reflectors 1.

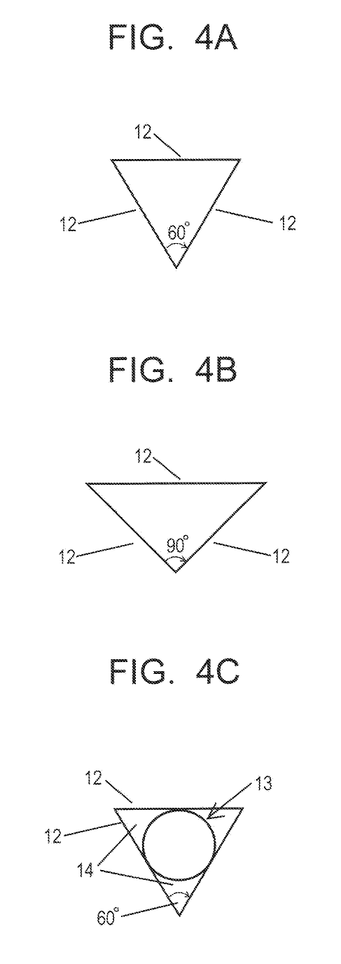

FIGS. 4a, b and c show cross-sectional drawings of three different possible triangular receiver configurations. The triangular receiver shape is particularly suited to be a receiver in the present invention. The triangular receiver tubes shown in FIGS. 4a, b and c may have a solar radiation absorbing coating on their outer surfaces and a heat collecting fluid circulated thru them or they may have photovoltaic solar cells attached to their outer surfaces 12. It is to be noted here that in the event solar cells are attached to the triangular receiver tubes a cooling fluid must be circulated thru them to cool the cells. The heat collected by said cooling fluid may then be used for other applications such as hot water, space heating, industrial process heat, absorption refrigeration and air conditioning, etc.

FIG. 4a shows a receiver tube whose cross section is an equilateral triangle.

FIG. 4b shows a receiver tube whose cross section is a right triangle. This right triangle receiver tube is especially suited to match the 90 degree angle of the underlying V trough Fresnel reflector structure of the embodiments shown in this document. However, it is again to be mentioned here that the present invention is not limited to the having an underlying V trough angle of 90 degrees and that, indeed, the present invention can be made with any underlying V angle.

FIG. 4c shows a receiver tube whose cross section is an equilateral triangle and on whose sides 12 are mounted solar cells. Inside and concentric with the triangular tube is a round tube 13. The round tube 13 is thermally bonded to the triangular tube by a heat transfer material 14 so that a cooling fluid can be circulated thru the round tube 13 to keep the solar cells from overheating.

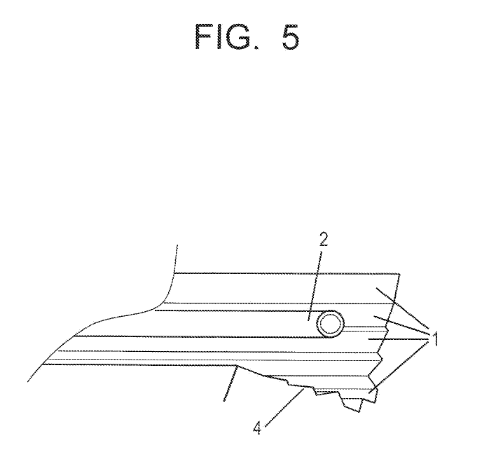

FIG. 5 is a perspective view showing the Fresnel reflectors 1 in the zig zag configuration 4 of the present invention, with a round receiver tube 2.

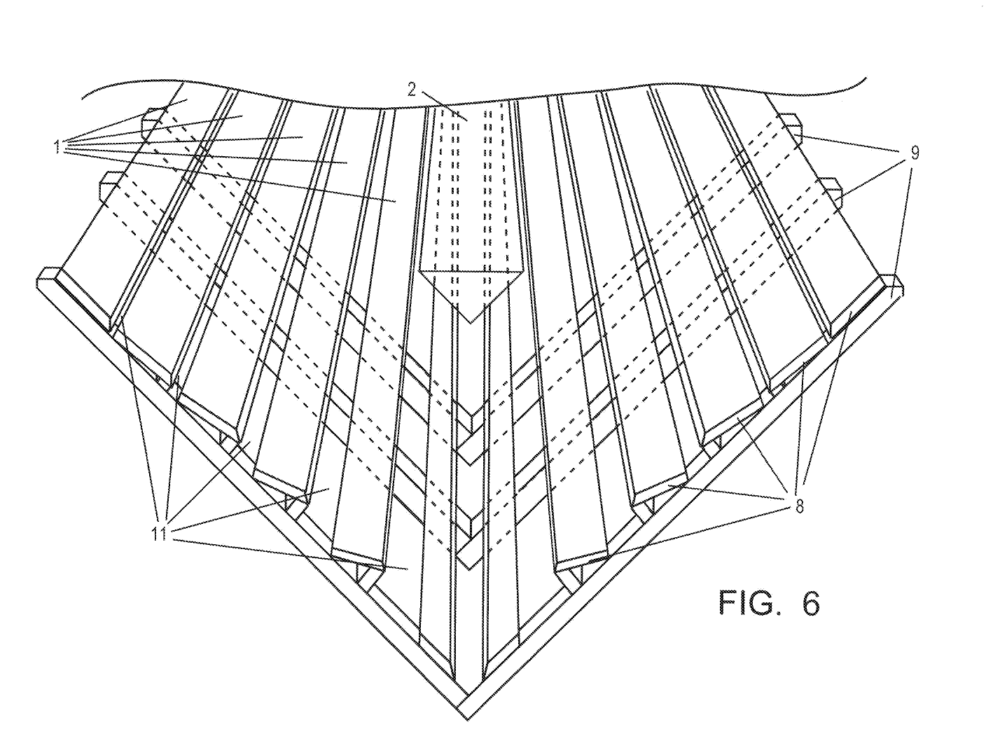

FIG. 6 is a perspective view showing the Fresnel reflectors 1 with the lattice support structure 5 of the present invention and a triangular receiver tube 2. Indicator 11 shows the spaces that naturally occur between the reflectors and the horizontal and vertical support members of the lattice support structure.

I claim:

1. A solar concentrator comprised of two panels disposed relative to each other to form a V shaped trough; each panel shaped to form a series of flat linear strips configured with reflective surfaces angled to create a Fresnel reflector that collectively reflect and concentrate incoming solar radiation that is parallel to the central planar axis of said trough to a central focal area that is parallel to the linear axis of said trough and located at or above the aperture opening of said trough; each panel further shaped to form a series of flat strips joining said reflective strips and configured not to intercept solar radiation that is parallel to the central axis of said trough.

2. The solar concentrator of claim 1 configured to create a concentrating solar collector with a solar energy receiving element disposed at said central focal area, to convert said concentrated solar energy to another form of energy for useful application.

3. The solar energy collector of claim 2 wherein the solar energy receiving element is a tube of cross-section designed to receive and absorb all the direct and reflected concentrated solar energy entering the collector and convert it to heat within a fluid passing through said tube.

4. The Solar energy collector of claim 2 wherein the solar energy receiving element is a structure of cross-section designed to support photovoltaic cells to receive and convert the solar energy entering the collector into electrical energy.

5. The solar energy collector of claim 4 wherein the solar energy receiving element is a triangular cross-section tube, upon whose surfaces are mounted photovoltaic cells to convert the direct and concentrated solar energy to electrical energy and thru which a fluid is circulated to cool said solar cells and convert solar energy, not converted to electrical energy, to heat.

6. A solar concentrator composed of a plurality of flat linear members with reflective surfaces arranged in the general shape of a linear trough with an underlying V shape and said flat linear members further oriented as Fresnel reflectors such that sunlight parallel to the trough central planar axis and falling upon said reflective surfaces is concentrated at a central focal area located at a position along the trough central axis at or above the aperture opening of said trough; said flat linear reflective members incorporated as the horizontal structural members of a lattice structure; linear vertical structural members inter-connected with said horizontal structural members, supporting said horizontal structural members and disposed at right angles to said horizontal structural members to form said structural lattice sides of said reflective V shaped trough concentrator.

7. A solar concentrator composed of a plurality of flat linear members with reflective surfaces arranged in the general shape of a linear trough with an underlying V shape and said flat linear members further oriented as Fresnel reflectors such that sunlight parallel to the trough central planar axis and falling upon said reflective surfaces is concentrated at a central focal area located at a position along the trough central axis at or above the aperture opening of said trough; said flat linear reflective members incorporated as the horizontal structural members of a lattice structure; linear diagonal structural members inter-connected with said horizontal structural members, supporting said horizontal structural members and disposed at oblique angles to said horizontal structural members to form said structural lattice sides of said reflective V shaped trough concentrator.

8. A solar concentrator composed of a plurality of flat linear members with reflective surfaces arranged in the general shape of a linear trough with an underlying V shape and said flat linear members further oriented as Fresnel reflectors such that sunlight parallel to the trough central planar axis and falling upon said reflective surfaces is concentrated at a central focal area located at a position along the trough central axis at or above the aperture opening of said trough; said flat linear reflective members incorporated as the horizontal structural members of a lattice structure; linear vertical structural members inter-connected with said horizontal structural members, supporting said horizontal structural members and disposed at right angles to said horizontal structural members and linear diagonal structural members inter-connected with said horizontal and vertical structural members, supporting said horizontal structural members and disposed at oblique angles to said horizontal and vertical structural members to form said structural lattice sides of said reflective V shaped trough concentrator.

9. The solar concentrator of claim 6 configured to create a concentrating solar collector with a solar energy receiving element disposed at said central focal area, to convert said concentrated solar energy to another form of energy for useful application.

10. The solar energy collector of claim 9 wherein the solar energy receiving element is a tube of cross-section designed to receive and absorb all the direct and reflected concentrated solar energy entering the collector and convert it to heat within a fluid passing through said tube.

11. The Solar energy collector of claim 9 wherein the solar energy receiving element is a structure of cross-section designed to support photovoltaic cells to receive and convert the solar energy entering the collector into electrical energy.

12. The solar energy collector of claim 11 wherein the solar energy receiving element is a triangular cross-section tube, upon whose surfaces are mounted photovoltaic cells to convert the direct and concentrated solar energy to electrical energy and thru which a fluid is circulated to convert solar energy, not converted to electrical energy, to heat.

13. The solar concentrator of claim 7 configured to create a concentrating solar collector with a solar energy receiving element disposed at said central focal area, to convert said concentrated solar energy to another form of energy for useful application.

14. The solar energy collector of claim 13 wherein the solar energy receiving element is a tube of cross-section designed to receive and absorb all the direct and reflected concentrated solar energy entering the collector and convert it to heat within a fluid passing through said tube.

15. The Solar energy collector of claim 13 wherein the solar energy receiving element is a structure of cross-section designed to support photovoltaic cells to receive and convert the solar energy entering the collector into electrical energy.

16. The solar energy collector of claim 15 wherein the solar energy receiving element is a triangular cross-section tube, upon whose surfaces are mounted photovoltaic cells to convert the direct and concentrated solar energy to electrical energy and thru which a fluid is circulated to convert solar energy, not converted to electrical energy, to heat.

17. The solar concentrator of claim 8 configured to create a concentrating solar collector with a solar energy receiving element disposed at said central focal area, to convert said concentrated solar energy to another form of energy for useful application.

18. The solar energy collector of claim 17 wherein the solar energy receiving element is a tube of cross-section designed to receive and absorb all the direct and reflected concentrated solar energy entering the collector and convert it to heat within a fluid passing through said tube.

19. The Solar energy collector of claim 17 wherein the solar energy receiving element is a structure of cross-section designed to support photovoltaic cells to receive and convert the solar energy entering the collector into electrical energy.

20. The solar energy collector of claim 19 wherein the solar energy receiving element is a triangular cross-section tube, upon whose surfaces are mounted photovoltaic cells to convert the direct and concentrated solar energy to electrical energy and thru which a fluid is circulated to convert solar energy, not converted to electrical energy, to heat.
